(19) United States
(12) Patent Application Publication
(10) Pub. No.: US 2019/0364671 A1
(43) Pub. Date: Nov. 28, 2019

(54) MOUNTING METHOD, MOUNTING DEVICE, AND PRODUCTION DEVICE

(71) Applicant: Sharp Kabushiki Kaisha, Sakai City, Osaka (JP)

(72) Inventors: Takushi MIHOTANI, Sakai City (JP); Motoji SHIOTA, Sakai City (JP)

(21) Appl. No.: 16/066,726

(22) PCT Filed: Mar. 29, 2017
(86) PCT No.: PCT/JP2017/013041

§ 371 Date: Jun. 28, 2018

(51) Int. Cl. H05K 3/36; H01L 27/32

(52) U.S. Cl. CPC H05K 3/361; H01L 27/3276; H01L 2227/326; H05K 2203/0165; H01L 2227/323; H05K 2203/0278

(57) ABSTRACT

A mounting method includes a generating pressing force that presses a non-active region against a backup stage, and a compression bonding an electronic circuit board to terminals, after the non-active region is pressed against the backup stage by the pressing force generated in the generating a pressing step.

### TECHNICAL FIELD

The disclosure relates to mounting of a flexible display device.

### BACKGROUND ART

In PTL 1, attention is paid that an inclination of a substrate surface tends to be the same inclination when using the same type of multilayer substrate, and a compression bonding device and a compression bonding method for an electronic component with bumps are disclosed that can improve mounting accuracy without causing a compression bonding head to perform a copying operation for each bump mounting point. Further, in PTL 2, a resin filling device is disclosed that is provided with a stage that holds a substrate in an inclined state, and an application head that fills the substrate with resin from a lower side of the inclination of the substrate.

### CITATION LIST

### Patent Literature

PTL 1: JP 11-26512 A (published Jan. 29, 1999)

PTL 2: JP 2008-218708 A (published Sep. 18, 2008)

### SUMMARY

### Technical Problem

However, the technology disclosed in PTL 1 and PTL 2 does not reduce warpage or buckling that occur in a flexible display that is a mounting target of an electronic circuit board.

An object of a first aspect of the disclosure is to realize a mounting method capable of leveling a flexible display and compression bonding an electronic circuit board.

### Solution to Problem

To resolve the above-described issues, a mounting method according to an aspect of the disclosure is a mounting method for mounting an electronic circuit board onto terminals included in a non-display region of a flexible display that includes a display region and the non-display region surrounding the display region. The mounting method includes generating a pressing force that presses the non-display region against a placement stage configured to allow the non-display region to be placed, and compression bonding the electronic circuit board to the terminals, after the non-display region is pressed against the placement stage using the pressing force generated in the generating a pressing force.

Furthermore, to resolve the above-described issues, a mounting device according to an aspect of the disclosure is a mounting device configured to mount an electronic circuit board onto terminals included in a non-display region of a flexible display that includes a display region and the non-display surrounding the display region. The mounting device includes a pressing unit configured to generate a pressing force that presses the non-display region against a placement stage configured to allow the non-display region to be placed, and a compression bonding unit configured to compression bond the electronic circuit board to the terminals of the non-display region pressed against the placement stage using the pressing force generated by the pressing unit.

### Advantageous Effects of Disclosure

According to an aspect of the disclosure, an effect is achieved of being able to level a flexible display and compression bond an electronic circuit board.

### BRIEF DESCRIPTION OF DRAWINGS

FIG. 1 is a flowchart illustrating an example of a production method of a flexible display.

FIG. 2A is a cross-sectional view illustrating a configuration (a state in which a layered body is formed on a substrate) of the flexible display during formation, and

FIG. 2B is a cross-sectional view illustrating a configuration example of the flexible display.

FIG. 3 is a plan view illustrating the configuration (the state in which the layered body is formed on the substrate) of the flexible display during formation.

FIG. 4A is a schematic diagram illustrating a configuration example of a mounting device according to a first embodiment, and FIG. 4B is a block diagram illustrating a configuration example of the mounting device.

FIG. 5 is a plan view illustrating a configuration example of a movable stage and a backup stage.

FIG. 6 is a plan view illustrating an example of an arrangement relationship between the backup stage and a compression bonding head.

FIGS. 7A to 7E are a flowchart illustrating an example of a mounting method of the electronic circuit board onto the flexible display according to the first embodiment.

FIGS. 8A and 8B are diagrams for explaining an advantageous effect of the mounting device.

FIGS. 9A and 9B are diagrams illustrating the mounting device according to a modified example of the first embodiment, where FIG. 9A is a cross-sectional view schematically illustrating the mounting device according to the modified example, and FIG. 9B is a diagram illustrating a configuration example of a pressing device.

FIGS. 10A to 10E are a flowchart illustrating an example of a mounting method of the electronic circuit board onto the flexible display according to the modified example of the first embodiment.

FIG. 11A is a schematic diagram illustrating a configuration example of a mounting device according to a second embodiment, and FIG. 11B is a block diagram illustrating a configuration example of the mounting device.

FIGS. 12A to 12I are a flowchart illustrating an example of a mounting method of the electronic circuit board onto the flexible display according to the second embodiment.

FIG. 13A is a schematic diagram illustrating a configuration example of a mounting device according to a third embodiment, and FIG. 13B is a block diagram illustrating a configuration example of the mounting device.

FIGS. 14A to 14J are a flowchart illustrating an example of a mounting method of the electronic circuit board onto the flexible display according to the third embodiment.

FIGS. 15A to 15G are a flowchart illustrating an example of a mounting method of the electronic circuit board onto the flexible display according to a modified example of the third embodiment.

### DESCRIPTION OF EMBODIMENTS

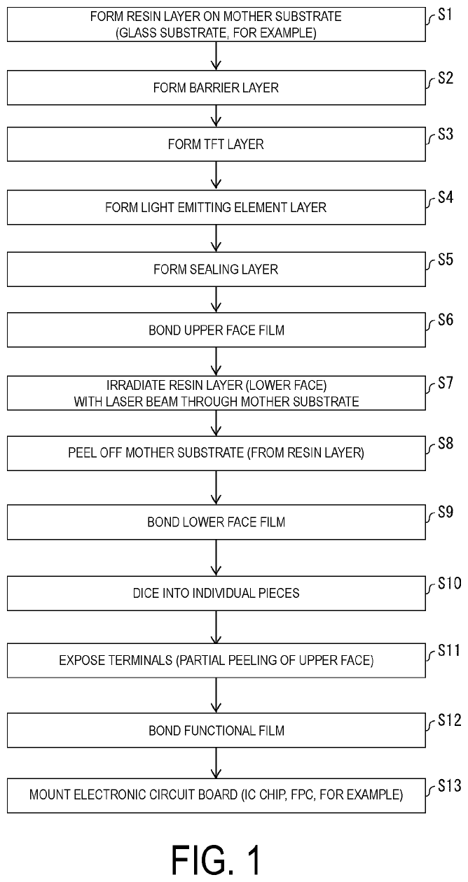

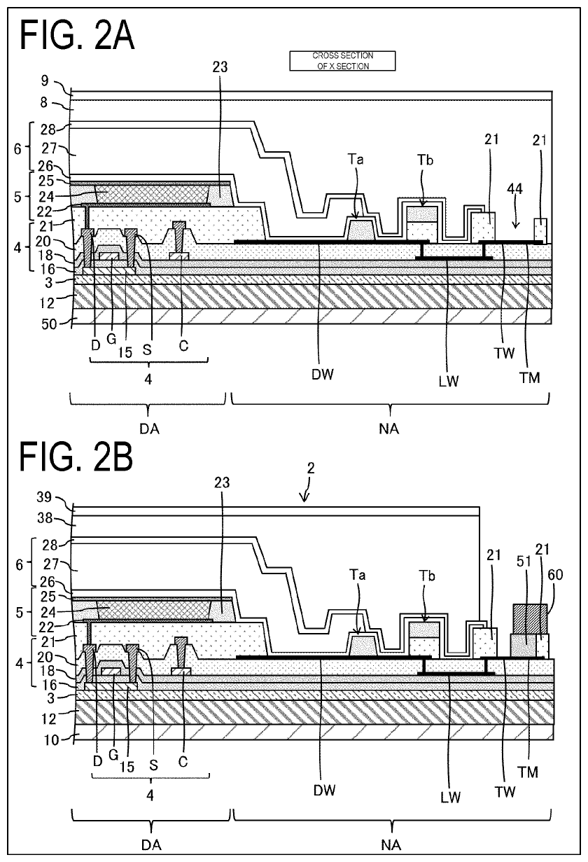

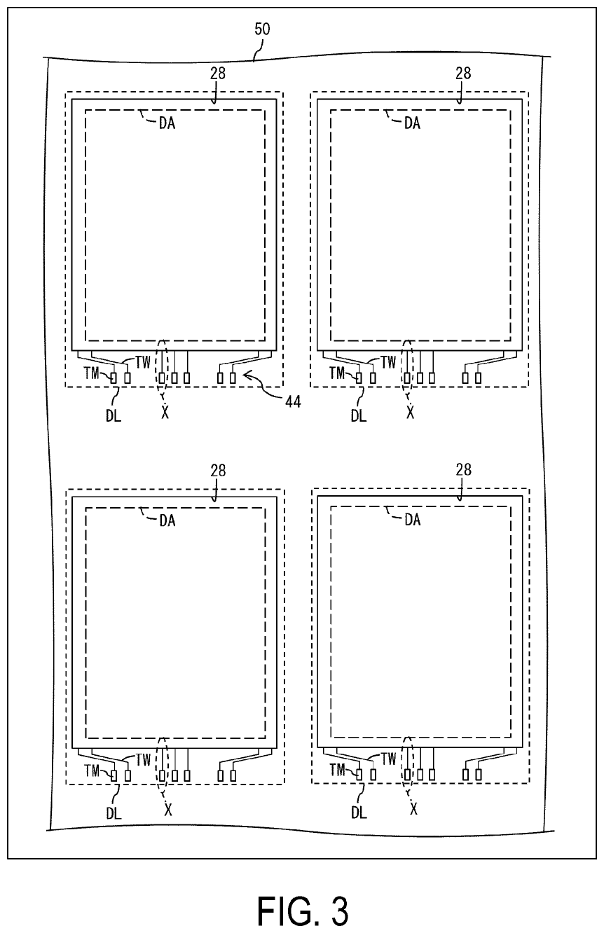

FIG. 1 is a flowchart illustrating an example of a production method of a flexible display. FIG. 2A is a cross-sectional view illustrating a configuration (a state in which a layered body is formed on a substrate) of the flexible display during formation, and FIG. 2B is a cross-sectional view illustrating a configuration example of the flexible display. FIG. 3 is a plan view illustrating the configuration (the state in which the layered body is formed on the substrate) of the flexible display during formation.

When the flexible display is produced, as illustrated in FIG. 1, FIG. 2A and FIG. 3, first, a resin layer 12 is formed on a transparent substrate 50 (a mother glass, for example) (step S1). Next, a barrier layer (an inorganic barrier film) 3 is formed (step S2). Next, a TFT layer 4 is formed (step S3). Next, a light emitting element layer (an OLED layer, for example) 5 is formed (step S4). Next, a sealing layer 6 is formed (step S5). Next, an upper face film 9 (a PET film, for example) is bonded to the sealing layer 6, with an adhesive layer 8 interposed therebetween (step S6).

Next, the lower face of the resin layer 12 is irradiated with a laser beam through the substrate 50 (step S7). Here, the resin layer 12 absorbs the laser beam with which the lower face of the substrate 50 has been irradiated and that has passed through the substrate 50, and as a result, the lower face of the resin layer 12 (an interface with the substrate 50) alters due to ablation, and a bonding strength between the resin layer 12 and the substrate 50 weakens. Next, the substrate 50 is peeled from the resin layer 12 (step S8). Next, as illustrated in FIG. 2B, a lower face film 10 (a PET film, for example) is bonded to the lower face of the resin layer 12, with an adhesive layer interposed therebetween (step S9). Then, a layered body including the lower film 10, the resin layer 12, the barrier layer 3, the TFT layer 4, the light emitting element layer 5, the sealing layer 6, and the upper face film 9 is divided along cutting lines DL illustrated in FIG. 3, and at the same time, the upper face film 9 is cut and a plurality of individual pieces are cut out (step S10). Next, terminal exposure is performed by peeling a part (a section on a terminal portion 44) of the upper face film 9 of the individual piece (step S11). Next, a functional film 39 is bonded to the upper side of the sealing layer 6 of the individual piece, with an adhesive layer 38 interposed therebetween (step S12). Then, an electronic circuit board 60 is mounted onto the terminal portion 44 of the individual piece, with an anisotropic conductive material 51 interposed therebetween (step S13). In this way, a flexible display 2 illustrated in FIG. 2B is obtained. Note that each of the above steps are performed by a production device of the flexible display.

Examples of the material used in the resin layer 12 include a polyimide, an epoxy, or a polyamide. Examples of the material used in the lower face film 10 include polyethylene terephthalate (PET).

The barrier layer 3 is a layer for preventing moisture or impurities from reaching the TFT layer 4 or the light emitting element layer 5 when the flexible display is used. The barrier layer 3 can be formed by CVD, for example, and can be configured by a silicon oxide film, a silicon nitride film, or a silicon oxinitride film, or by a layered film of these films.

The TFT layer 4 includes a semiconductor film 15, an inorganic insulating film 16 (a gate insulating film) formed on the semiconductor layer 15, a gate electrode G formed on the inorganic insulating film 16, an inorganic insulating film 18 formed on the gate electrode G, a capacity wire C formed on the inorganic insulating film 18, an inorganic insulating film 20 formed on the capacity wire C, a source electrode S and a drain electrode D formed on the inorganic insulating film 20, and a flattening film 21 formed on the source electrode S and the drain electrode D.

A thin film transistor (TFT) is configured to include the semiconductor film 15, the inorganic insulating film 16, and the gate electrode G. The source electrode S is connected to a source region of the semiconductor film 15, and the drain electrode D is connected to a drain region of the semiconductor film 15.

The semiconductor film 15 is formed of low-temperature polysilicon (LTPS) or an oxide semiconductor, for example. The inorganic insulating film 16 can be formed by CVD, for example, and can be configured by a silicon oxide (SiOx) film, a silicon nitride (SiNx) film, or by a layered film of these films. The gate electrode G, the source electrode (source wire) S, the drain electrode (drain wire) D, and the terminals, for example, are configured by a single layer of a metal including at least one of aluminum (Al), tungsten (W) molybdenum (Mo), tantalum (Ta), chromium (Cr), titanium (Ti), or copper (Cu), or a layered film of these. Note that, in FIGS. 2A and 2B, the TFT is illustrated that has a top gate configuration in which the semiconductor film 15 forms the channel, but the TFT may have a bottom gate configuration (when the TFT channel is the oxide semiconductor, for example).

The inorganic insulating films 18 and 20 can be formed by CVD, for example, and can be configured by a silicon oxide (SiOx) film, a silicon nitride (SiNx) film, or by a layered film of these films. The flattening film (interlayer insulating film) 21 can be formed, for example, of a coatable photosensitive organic material such as a polyimide, an acrylic, or the like.

The terminal portion 44 is provided on an end portion (a non-active region NA) of the TFT layer 4. The terminal portion 44 includes a terminal TM that is used for connecting an IC chip or the electronic circuit board 60 such as a flexible printed circuit board (FPC), and a terminal wire TW connected to the terminal TM. The terminal wire TW is electrically connected to various wires of the TFT layer 4 via a relay wire LW and a lead-out wire DW.

The terminal TM, the terminal wire TW, and the lead-out wire DW are formed in the same process as the source electrode S, for example, and thus, are formed in the same layer (on the inorganic insulating film 20) and of the same material (two layers of titanium film and an aluminum film sandwiched between the two layers of titanium film, for example) as the source electrode S. The relay wire LW is formed in the same process as the capacity wire C, for example. End faces (edges) of the terminal TM, the terminal wire TW, and the lead-out wire DW are covered by the flattening film 21.

The light emitting element layer 5 (an organic light emitting diode layer, for example) includes an anode electrode 22 formed on the flattening film 21, a bank (pixel partition) 23 that defines a sub pixel of an active region DA, an EL (electroluminescence) layer 24 formed on the anode electrode 22, and a cathode electrode 25 formed on the EL layer 24, and a light emitting element (an organic light emitting diode (OLED), for example) is configured by the anode electrode 22, the EL layer 24, and the cathode electrode 25.

The EL layer 24 is formed in a region (a sub pixel region) surrounded by the bank 23, by vapor deposition or an ink-jet method. When the light emitting element layer 5 is the organic light emitting diode (OLED) layer, the EL layer 24 is formed, for example, by layering a hole injecting layer, a hole transport layer, a light emitting layer, an electron transport layer, and an electron injecting layer, in this order from a lower layer side.

The anode electrode (positive electrode) 22 is formed by layering Indium Tin Oxide (ITO) and an alloy containing Ag, for example, and has light reflectivity (to be described below in more detail). The cathode electrode 25 can be formed of a transparent electrically conductive material such as Indium Tin Oxide (ITO) and Indium Zinc Oxide (IZO).

When the light emitting element layer 5 is the OLED layer, holes and electrons are recombined inside the EL layer 24 by a drive current between the anode electrode 22 and the cathode electrode 25, and light is emitted as a result of excitons that are generated by the recombination falling into a ground state. Since the cathode electrode 25 is transparent, and the anode electrode 22 is light-reflective, the light emitted from the EL layer 24 travels upwards and results in top emission.

The light emitting element layer 5 is not limited to being configured by the OLED element, and may be configured by an inorganic light emitting diode or a quantum dot light emitting diode.

A bulging body Ta and a bulging body Tb that define edges of the organic sealing film 27 are formed in the non-active region NA. The bulging body Ta functions as a liquid stopper when the organic sealing film 27 is applied using an ink-jet method, and the bulging body Tb functions as a backup liquid stopper. Note that a lower portion of the bulging body Tb is configured by the flattening film 21, and functions as a protection film for an end face of the lead-out wiring DW. The bank 23, the bulging body Ta, and an upper portion of the bulging body Tb can be formed in the same process, for example, by using a coatable photosensitive organic material such as a polyimide, an epoxy, or an acrylic.

The sealing layer 6 is transparent, and includes the first inorganic sealing film 26 covering the cathode electrode 25, the organic sealing film 27 formed on the first inorganic sealing film 26, and the second inorganic sealing film 28 covering the organic sealing film 27.

The first inorganic sealing film 26 and the second inorganic sealing film 28 can each be configured, for example, by a silicon oxide film, a silicon nitride film, or a silicon oxinitride film, or by a layered film of these, formed using CVD. The organic sealing film 27 is thicker than the first inorganic sealing film 26 and the second inorganic sealing film 28, is a transparent organic film, and can be formed of a coatable photosensitive organic material such as a polyimide, or an acrylic. For example, after applying an ink containing such an organic material onto the first inorganic sealing film 26 using the ink-jet method, the ink is cured by UV irradiation. The sealing layer 6 covers the light emitting element layer 5 and inhibits foreign matter, such as water and oxygen, from penetrating the light emitting element layer 5.

Note that the upper face film 9 is bonded onto the sealing layer 6 with the adhesive layer 8 interposed therebetween, and also functions as a support when the substrate 50 is peeled off. Examples of a material of the upper face film 9 include polyethylene terephthalate (PET).

The lower face film 10 is formed of PET or the like, and, by being bonded to the lower face of the resin layer 12 after the substrate 50 has been peeled off, functions as a support material and a protection material.

The functional film 39 has an optical compensation function, a touch sensor function, a protective function or the like, for example. The electronic circuit board 60 is the IC chip or the flexible printed circuit board that is mounted on the plurality of terminals TM, for example. Note that the IC chip may be the IC chip with a bump.

Above, the description is given for a case of producing the flexible display, but when a non-flexible display device is to be produced, since the peeling of the substrate and the like is not required, the process may advance from step S6 to step S10 illustrated in FIG. 1, for example.

Note that, the flexible display is an example of an application of the flexible device. The flexible display device is not particularly limited to a specific display device, as long as it is a display panel that has flexibility (elastic behavior), and is provided with bendable optical elements. The optical element is an optical element whose luminance and transmittance are controlled by an electric current, and examples of the electric current-controlled optical element include an organic Electro Luminescence (EL) display provided with an Organic Light Emitting Diode (OLED), an EL display such as an inorganic EL display provided with an inorganic light emitting diode, or a QLED display provided with a Quantum Dot Light Emitting Diode (QLED). Furthermore, examples of a voltage-controlled optical element include a liquid crystal display element.

### First Embodiment

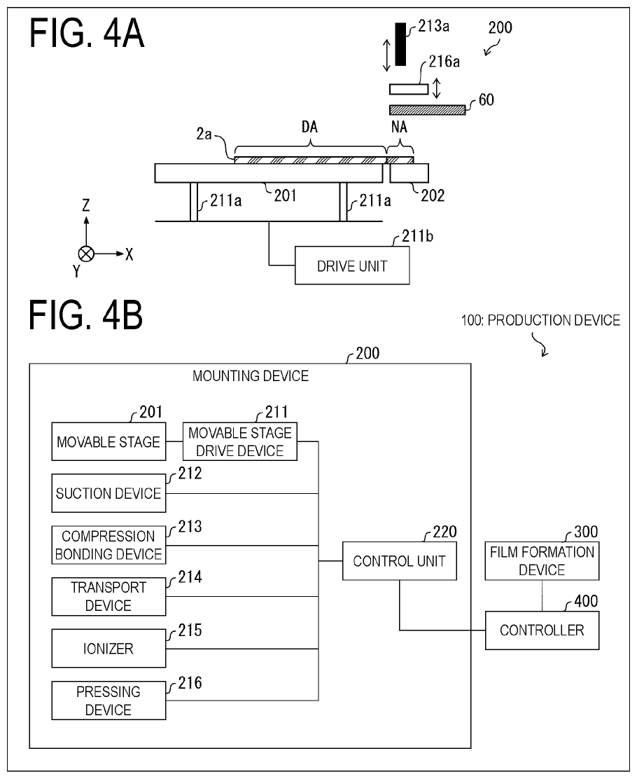

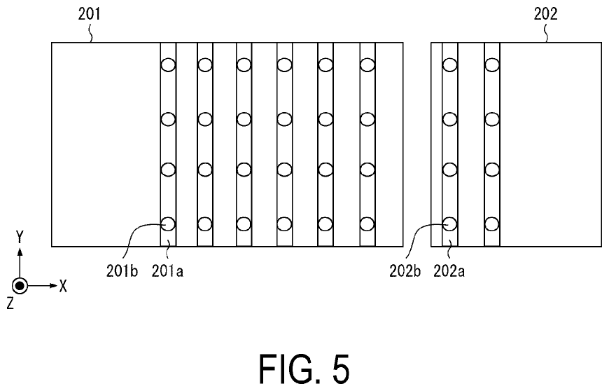

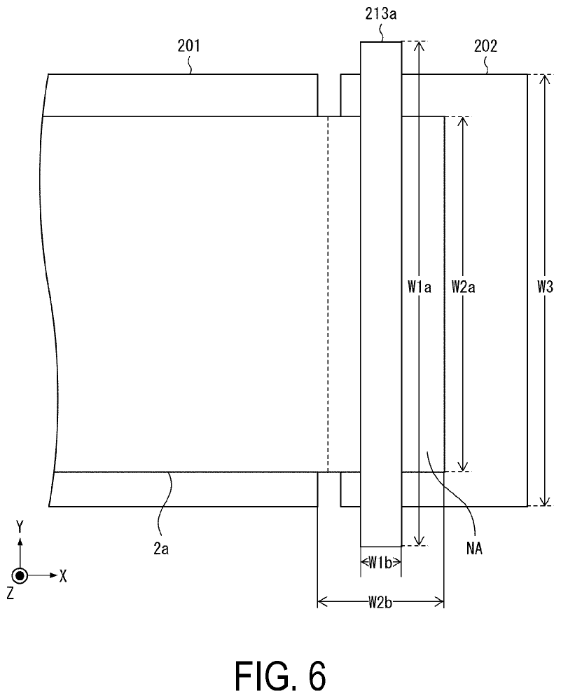

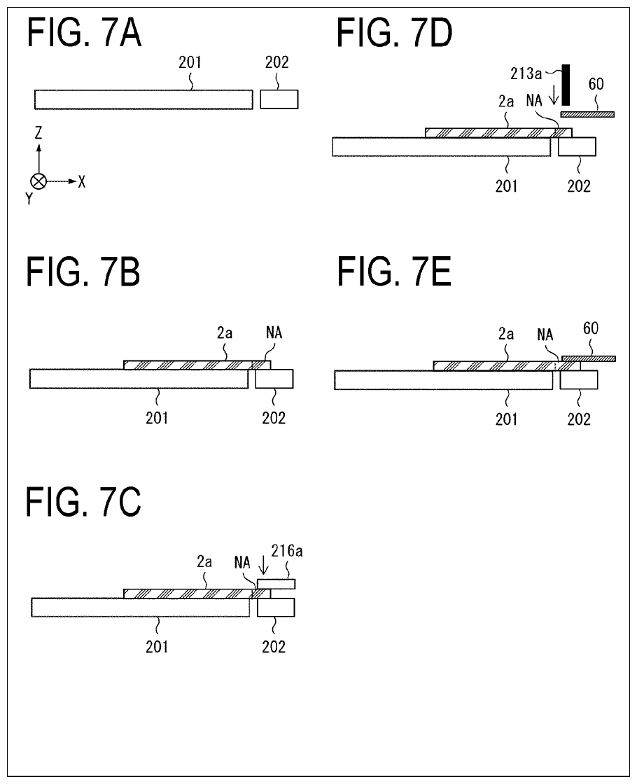

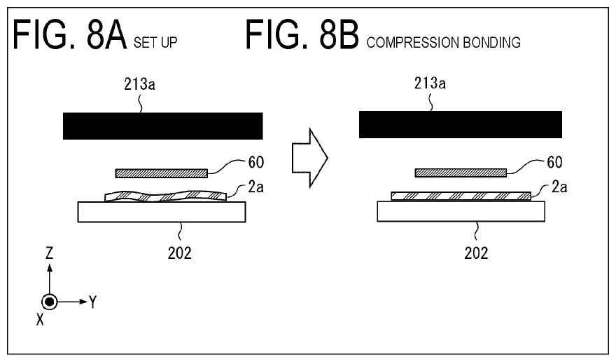

A configuration of a production device 100, and in particular a configuration of a mounting device 200 for a flexible display 2a according to the present embodiment will be described with reference to FIG. 4A to FIG. 8B. FIG. 4A is a schematic diagram illustrating a configuration example of the mounting device 200, and FIG. 4B is a block diagram illustrating a configuration example of the mounting device 200. FIG. 5 is a plan view illustrating a configuration example of a movable stage 201 and a backup stage 202 (a placement stage, a compression bonding stage). FIG. 6 is a plan view illustrating an example of an arrangement relationship between the backup stage 202 and a compression bonding head 213a. FIGS. 7A to 7E are a flowchart illustrating an example of a mounting method of the electronic circuit board 60 onto the flexible display 2a. FIGS. 8A and 8B are diagrams for explaining an advantageous effect of the mounting device 200.

Below, a description is given in which a flexible display which is formed through processing at steps 51 to S12 illustrated in FIG. 1 and on which the electronic circuit board 60 is not yet mounted is referred to as the “flexible display 2a,” and a flexible display after the electronic circuit board 60 has been mounted is referred to as the “flexible display 2” (see FIG. 2B).

### Production Device

A description will be made of the production device 100 that produces the flexible display 2, with reference to FIG. 4B. As illustrated in FIG. 4B, the production device 100 is provided with a mounting device 200 described below, a film formation device 300 configured to form each of layers configuring the flexible display 2, and a controller 400 configured to control these devices.

### Mounting Device

The mounting device 200 is a device for mounting the electronic circuit board 60 onto the terminals TM of the non-active region NA of the flexible display 2a. In the flexible display 2a, the active region DA is a display region including at least the anode electrode 22 and the cathode electrode 25, and the non-active region NA is a non-display region surrounding the active region DA and including at least the terminals TM. The mounting device 200 includes the movable stage 201, the backup stage 202, a movable stage drive device 211, a suction device 212, a compression bonding device 213 (compression bonding unit), a transport device 214, an ionizer 215, and a pressing device 216 (pressing unit). Furthermore, the mounting device 200 is provided with a control unit 220 configured to perform overall control of the movable stage drive device 211, the suction device 212, the compression bonding device 213, the transport device 214, the ionizer 215, and the pressing device 216.

The flexible display 2a on which the electronic circuit board 60 is to be mounted is placed on the movable stage 201. Mainly, the active region DA of the flexible display 2a is placed on the movable stage 201. In other words, at least a section of the non-active region NA on which the terminals TM are formed is placed in a state of protruding from the movable stage 201 and facing the backup stage 202. An alignment mark may be provided on the surface of the movable stage 201 to define a position at which the flexible display 2a is to be placed so that placement is possible in this state.

Furthermore, to perform fine adjustment in order to place the non-active region NA at a position defined on the backup stage 202, the movable stage 201 moves in an X axis or a Y axis direction. The movement of the movable stage 201 in the X axis and the Y axis directions is performed by the movable stage drive device 211. Note that, the X axis direction is a direction in which a side surface of the movable stage 201 and a side surface of the backup stage 202 face each other, and the Y axis direction is a direction that is perpendicular to the X axis direction and a Z axis direction. The Z axis direction is a direction substantially perpendicular to the surface of the backup stage 202 on which the non-active region NA is placed.

The movable stage drive device 211 supports the movable stage 201 and also moves the movable stage 201 in the X axis or the Y axis direction. For example, the movable stage drive device 211 is provided with a support member 211a that is connected to the lower face of the movable stage 201 and that supports the movable stage 201, and a drive unit 211b configured to move the support member 211a (namely, the movable stage 201) in the X axis or the Y axis direction. More specifically, the movable stage drive device 211 is provided with a movement mechanism that is provided on a lower end of the support member 211a and that enables the movement in the X axis or the Y axis direction, and the above-described movement is realized by the movement mechanism being driven by the drive unit 211b.

The backup stage 202 is mainly used for placing, of the flexible display 2a, at least the section of the non-active region NA on which the terminals TM are formed. More specifically, the plurality of terminals TM of the flexible display 2a, which are to be compression bonded with a plurality of terminals provided on the electronic circuit board 60, are placed on the backup stage 202. In a state in which the non-active region NA is placed on the backup stage 202 and the electronic circuit board 60 is placed on top of the non-active region NA, the electronic circuit board 60 is thermocompression bonded to the plurality of terminals TM with the compression bonding head 213a (the compression bonding unit). As a result, the electronic circuit board 60 is mounted on the flexible display 2a. As described above, the anisotropic conductive material 51 is disposed on the plurality of terminals TM (the terminal portion 44), and the plurality of terminals TM and the plurality of terminals of the electronic circuit board 60 are compression bonded via the anisotropic conductive material 51. By performing the compression bonding via the anisotropic conductive material 51, it is possible to inhibit unintentional electrical conduction between the terminals during the compression bonding.

Since the electronic circuit board 60 is mounted on the flexible display 2a on the backup stage 202, it is necessary to accurately determine the position of the flexible display 2a with respect to the backup stage 202. Thus, the alignment mark is provided on the surface of the backup stage 202 to define a position at which the flexible display 2a is to be placed. The movable stage 201 places the non-active region NA on the backup stage 202 so as to align the flexible display 2a with the alignment mark.

Note that the determining of the position of the flexible display 2a with respect to the movable stage 201 or the backup stage 202 is performed, for example, by the control unit 220 analyzing captured images of an image capturing device (not illustrated) configured to capture an image of each of the surfaces of the movable stage 201 and the backup stage 202.

The material of the movable stage 201 and of the backup stage 202 is glass. In particular, since the electronic circuit board 60 is compression bonded to the plurality of terminals TM on the backup stage 202, the surface of the backup stage 202 needs be precisely leveled, in order to prevent uneven pressure during the compression bonding. In the case of glass, since the glass is easily processed, the surfaces of the movable stage 201 and the backup stage 202 are easily leveled. Note that, as long as the surfaces thereof can be leveled, the movable stage 201 and the backup stage 202 may be formed of a material other than glass.

As illustrated in FIG. 5, the movable stage 201 is provided with groove portions 201a and openings 201b. Furthermore, the backup stage 202 is provided with groove portions 202a and openings 202b. The groove portions 201a and 202a are provided along the Y axis direction in the movable stage 201 and the backup stage 202, respectively, and are disposed side by side along the X axis direction. Furthermore, the openings 201b and 202b are respectively provided in the bases of the groove portions 201a and 202a. The openings 201b and 202b are provided in order to apply suction to the flexible display 2a placed on each of the movable stage 201 and the backup stage 202, and are connected to the suction device 212.

By providing the openings 201b and 202b connected to the suction device 212 and driving the suction device 212, the flexible display 2a placed on the movable stage 201 or the backup stage 202 can be held on the movable stage 201 or the backup stage 202. Furthermore, by providing the openings 201b in the groove portions 201a, and the openings 202b in the groove portions 202a, localized suction regions defined by the openings 201b and 202b can be spread to the whole of the groove portions 201a and 202a.

Furthermore, when, on the backup stage 202, the groove portion 202a is present in a compression bonding position of the compression bonding head 213a, there is a possibility that, during the compression bonding, the non-active region NA may sink toward the groove portion 202a side along the groove portion 202a. It is thus preferable for the groove portion 202a not to be provided at the above-described compression bonding position.

In the present embodiment, a plurality of the groove portions 201a in which a plurality of the openings 201b are provided are provided in the movable stage 201, and a plurality of the groove portions 202a in which a plurality of the openings 202b are provided are provided in the backup stage 202, but the configuration is not limited to this example. Specifically, it is sufficient that the groove portions 201a and 202a and/or the openings 201b and 202b be provided such that the flexible display 2a is held on the movable stage 201 and the backup stage 202 by the suction of the suction device 212.

For example, the number of openings 201b and 202b provided in the groove portions 201a and 202a, respectively, may be one, and may be provided in a side portion of each of the groove portions 201a and 202a, rather than in the base thereof. Furthermore, the extending direction of the groove portions 201a and 202a is not limited to the Y axis direction, and may be, for example, the X axis direction, and the number thereof may be one. In addition, the groove portions 201a and 202a need not necessarily be provided, and only the plurality of openings 201b and 202b may be provided. In this case also, the number of provided openings 201b and 202b may be one.

The suction device 212 causes the flexible display 2a placed on the movable stage 201 or the backup stage 202 to be sucked against the movable stage 201 or the backup stage 202. The suction device 212 is connected to the openings 201b of the movable stage 201 and to the openings 202b of the backup stage 202, and realizes the above-described suction by generating a suction force using a vacuum, for example.

As described above, the arrangement position of the flexible display 2a with respect to the backup stage 202 is vital to the mounting of the electronic circuit board 60. The flexible display 2a that has been aligned with a predetermined position on the backup stage 202 thus needs to be fixed in the aligned position, at least during the thermocompression bonding of the electronic circuit board 60. Therefore, the suction force of the suction device 212 with respect to the backup stage 202, and the number, the layout positions and the shapes of the groove portions 202a and of the openings 202b need to be more precisely defined than the suction force and the like with respect to the movable stage 201, so that the flexible display 2a is reliably fixed in the predetermined position, at least during the thermocompression bonding.

Note that a porous plate may be used as the movable stage 201 and the backup stage 202, and the suction device 212 may be connected to the porous plate. In this case, the suction can be applied to the flexible display 2a without providing the groove portions 201a and the openings 201b, and the groove portions 202a and the openings 202b in the movable stage 201 and the backup stage 202, respectively. When seen from this point of view, the porous plate is preferably used as the movable stage 201 and the backup stage 202.

The compression bonding device 213 is pressed against the backup stage 202 by the pressing device 216, and the plurality of terminals of the electronic circuit board 60 are compression bonded (thermocompression bonded) to the plurality of terminals TM of the leveled non-active region NA. The electronic circuit board 60 is thus mounted on the flexible display 2a. The compression bonding device 213 is provided with the compression bonding head 213a configured to compression bond the plurality of terminals TM and the plurality of terminals of the electronic circuit board 60. The compression bonding head 213a is provided in a position facing the backup stage 202 (above the backup stage 202).

The compression bonding device 213 is configured to compression bond the plurality of terminals TM and the plurality of terminals of the electronic circuit board 60 at a set temperature (approximately 170° C., for example), a set pressure (several MPa, for example), and a set compression bonding time (from 3 to 5 seconds, for example). For these compression bonding conditions, recommended values for the compression bonding of these terminals are set (values that also take into account the characteristics of the anisotropic conductive material 51 interposed between the terminals). Furthermore, the values are set in accordance with a size and the like of the section of the flexible display 2a that is compression bonded. In addition, the above-described compression bonding conditions of the compression bonding device 213 may be determine using a test piece flexible display.

As illustrated in FIG. 6, a length of the compression bonding head 213a (a length in the Y axis direction) W1a is longer than a width W2a of the flexible display 2a placed on the backup stage 202. In the present embodiment, the length W1a of the compression bonding head 213a is longer than a width W3 of the backup stage 202. This allows the plurality of terminals TM on the flexible display 2a to be compression bonded. Furthermore, the compression bonding can be applied to the flexible displays 2a having various widths W2a, and general-purpose properties of the compression bonding head 213a can be improved. However, as long as the length W1a of the compression bonding head 213a is longer than the width W2a of the flexible display 2a, the length W1a may be equal to or less than the width W3 of the backup stage 202. Furthermore, it is sufficient that a width of the compression bonding head 213a (a length in the X axis direction) W1b be of a length that is able to cover all of the plurality of terminals TM of the flexible display 2a, and is from 0.5 to 5 mm, for example.

The transport device 214 transports the flexible display 2a and the electronic circuit board 60 to predetermined positions. For example, the transport device 214 places the flexible display 2a on the movable stage 201 and the backup stage 202. Furthermore, the transport device 214 places the electronic circuit board 60 on the backup stage 202 (on the flexible display 2a placed on the backup stage 202). For example, the transport device 214 applies suction to the flexible display 2a or the electronic circuit board 60 and transports each to the predetermined position, then releases the suction at the predetermined position. In this way, the flexible display 2a or the electronic circuit board 60 is placed in the predetermined position.

The ionizer 215 emits positive ions and negative ions, and eliminates static electricity generated by the flexible display 2a or the electronic circuit board 60. The static electricity can occur in the flexible display 2a or the electronic circuit board 60 when: (1) the flexible display 2a is placed on the movable stage 201 or the backup stage 202; (2) the flexible display 2a on which the electronic circuit board 60 has been mounted is removed from the movable stage 201 or the backup stage 202; and (3) the electronic circuit board 60 is mounted on the flexible display 2a. Thus, the ionizer 215 is disposed around the periphery of the movable stage 201 and the backup stage 202.

The pressing device 216 generates a pressing force that presses the non-active region NA placed on the backup stage 202 against the backup stage 202. More specifically, the pressing device 216 is provided with a pressing member 216a, drives the pressing member 216a, and, after moving the pressing member 216a to the non-active region NA, presses the non-active region NA against the backup stage 202 (applies pressure). In other words, in the present embodiment, the pressing force is generated using the pressing member 216a.

By the pressing member 216a pressing the non-active region NA, which is placed on the backup stage 202 and which includes the plurality of terminals TM, against the backup stage 202, the region including the plurality of terminals TM can be leveled, and a state can be obtained in which the electronic circuit board 60 can be mounted on the flexible display 2a. It is sufficient that the material of the pressing member 216a be a material that can level the region, and is glass, for example.

It is sufficient that a pressure of the pressing and a pressing time be of a degree that can level the non-active region NA, and may be determined in accordance with the material of the backup stage 202 and the pressing member 216a, or the like. Furthermore, when the movable stage 201 is moving, the pressing device 216 causes the pressing member 216a to retract to a position in which the pressing member 216a does not collide with the non-active region NA protruding from the movable stage 201.

### Mounting Method

Next, a mounting method (mounting processing) of the electronic circuit board 60 onto the plurality of terminals TM of the flexible display 2a by the mounting device 200 will be described with reference to FIGS. 7A to 7E. The present mounting method is realized by each of the above-described devices being controlled by the control unit 220.

As illustrated in FIG. 7A, with respect to the movable stage 201 on which the flexible display 2a has not yet been placed (an initial state), the movable stage 201 and the backup stage 202 are disposed such that side surfaces of each face each other. In this state, as illustrated in FIG. 7B, the transport device 214 places the flexible display 2a on the movable stage 201 and the backup stage 202 such that the non-active region NA protrudes from the movable stage 201 and faces the backup stage 202. At this time, the control unit 220 drives the movable stage drive device 211 and causes the movable stage 201 to move. In this way, the position alignment of the flexible display 2a with respect to the backup stage 202 is performed so that the non-active region NA is placed in the predetermined position on the backup stage 202. When the flexible display 2a is placed on the movable stage 201 and the backup stage 202, the suction device 212 starts the suction, and causes the flexible display 2a to be sucked against the movable stage 201 and the backup stage 202 (a suction process).

After the non-active region NA has been placed on the backup stage 202 and fixed in place, the suction device 212 temporarily stops the suction with respect to the backup stage 202. After that, as illustrated in FIG. 7C, after the pressing device 216 moves the pressing member 216a to the non-active region NA, the non-active region NA is pressed by the pressing member 216a and the non-active region NA is pressed against the backup stage 202 (a pressing process). After the non-active region NA is pressed and leveled, the pressing device 216 returns the pressing member 216a to a pre-pressing position. Furthermore, at that time, the suction device 212 once again starts the temporarily stopped suction. By temporarily stopping the suction during the pressing, the possibility can be reduced of the flexible display 2a sinking toward the groove portion 202a side (obstructing the leveling) due to the pressing.

In other words, the suction device 212 releases a suction state of the non-active region NA with respect to the backup stage 202 during a period in which the pressing member 216a is generating the pressing force.

After that, as illustrated in FIG. 7D, the transport device 214 transports the electronic circuit board 60 to a position above the non-active region NA. More specifically, the transport device 214 aligns the position of the electronic circuit board 60 with respect to the flexible display 2a, so that the plurality of terminals of the electronic circuit board 60 face the plurality of terminals TM of the non-active region NA. While the position alignment is being performed, the electronic circuit board 60 is in a non-contact state with respect to the flexible display 2a. When the position alignment is complete, the compression bonding device 213 moves the compression bonding head 213a toward the backup stage 202, and compression bonds the plurality of terminals of the electronic circuit board 60 with the plurality of terminals TM (a compression bonding process). A state obtained when the compression bonding is complete is illustrated in FIG. 7E. When the compression bonding is complete, the compression bonding device 213 moves the compression bonding head 213a upward (to a pre-compression bonding position), and at the same time, the suction device 212 stops the suction with respect to the movable stage 201 and the backup stage 202. After that, the transport device 214 transports the flexible display 2a on which the electronic circuit board 60 is mounted to a subsequent process, and at the same time, places the new flexible display 2a on which the electronic circuit board 60 is to be mounted, on the movable stage 201 (the state illustrated in FIG. 7B).

### Effects of Present Embodiment

Since the flexible display 2a has flexibility, warpage and buckling occur in the flexible display 2a itself (the flexible display 2a is bent even in a normal state). Thus, as illustrated in FIG. 8A, the leveling of the flexible display 2a is difficult when the flexible display 2a is simply placed on the backup stage 202. Even when the flexible display 2a is sucked against the backup stage 202 by the suction device 212, the warpage and buckling are not easily leveled.

In the production method of the present embodiment, the pressing member 216a is used to press the non-active region NA, and after that, the electronic circuit board 60 is compression bonded to the plurality of terminals TM. Thus, as illustrated in FIG. 8B, the flexible display 2a placed on the backup stage 202 can be leveled, and the electronic circuit board 60 can be mounted on the plurality of terminals TM.

### Modified Example

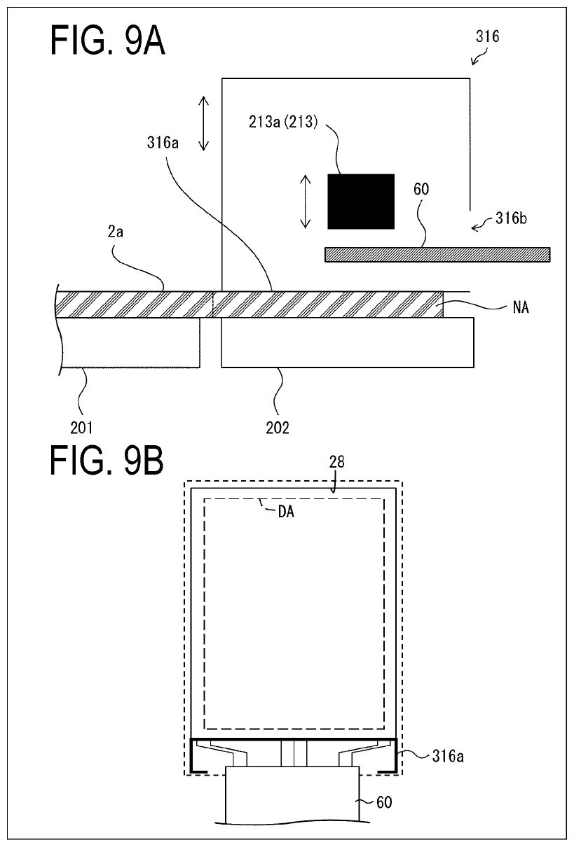

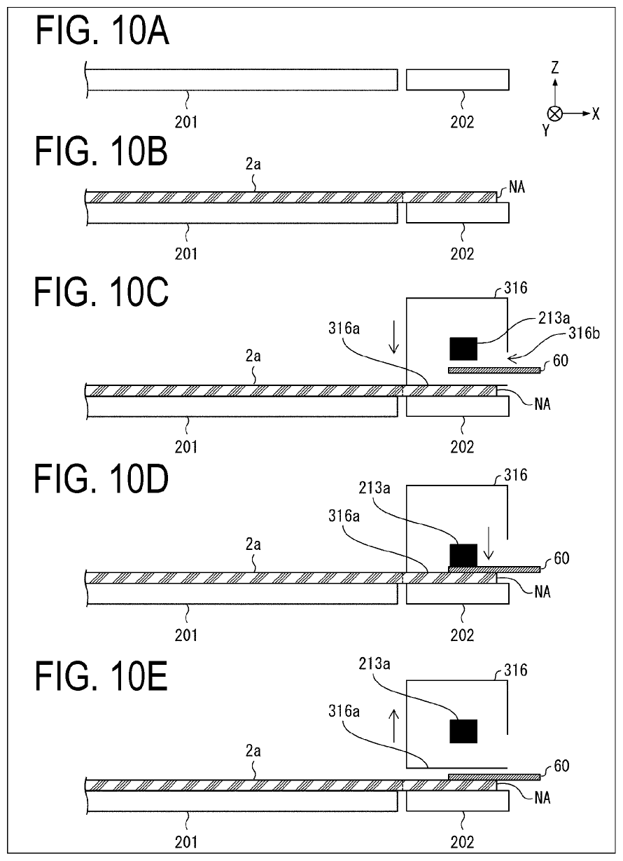

A modified example of the first embodiment will be described with reference to FIGS. 9A and 9B, and FIGS. 10A to 10E. FIGS. 9A and 9B are diagrams illustrating a modified example of the mounting device 200. FIG. 9A is a cross-sectional view schematically illustrating the modified example of the mounting device 200, and FIG. 9B is a diagram illustrating a configuration example of a pressing device 316. FIGS. 10A to 10E are a flowchart illustrating an example of a mounting method of the electronic circuit board 60 onto the flexible display 2a.

In the above-described first embodiment, the compression bonding device 213 and the pressing device 216 are separate bodies, but in the present modified example, as illustrated in FIG. 9A, the pressing device 316 is disposed so as to face the backup stage 202, and at least the compression bonding head 213a of the compression bonding device 213 is disposed inside the pressing device 316. The pressing device 316 is controlled by the control unit 220, and can move upward and downward so as to be able to press the non-active region NA placed on the backup stage 202. In the present modified example, a base 316a of the pressing device 316 functions as a pressing member that presses the non-active region NA placed on the backup stage 202. Furthermore, the compression bonding head 213a moves upward and downward inside the compression bonding head 316. A housing (including the base 316a) of the compression bonding head 316 and the compression bonding head 213a can be controlled to move independently of each other.

In addition, as illustrated in FIGS. 9A and 9B, an insertion opening 316b, into which the electronic circuit board 60 can be inserted, is provided in a side portion of the pressing device 316. As illustrated in FIG. 9B, the base 316a is formed in a frame shape so that the electronic circuit board 60 can be compression bonded to the non-active region NA in a state in which the electronic circuit board 60 is inserted into the interior of the pressing device 316.

### Mounting Method

Processes illustrated in FIGS. 10A and 10B are the same as the processes illustrated in FIGS. 7A and 7B. In FIG. 10B, the suction device 212 starts the suction, and causes the flexible display 2a to be sucked against the movable stage 201 and the backup stage 202. After that, as illustrated in FIG. 10C, the transport device 214 transports the electronic circuit board 60 in the interior of the pressing device 316, via the insertion opening 316b. When the electronic circuit board 60 is transported, the control unit 220 causes the pressing device 316 to move as far as the non-active region NA and the base 316a to be pressed against the non-active region NA.

After that, the transport device 214 aligns the position of the electronic circuit board 60 with respect to the flexible display 2a, such that the plurality of terminals of the electronic circuit board 60 face the plurality of terminals TM of the non-active region NA. When the position alignment is complete, as illustrated in FIG. 10D, the compression bonding device 213 moves the compression bonding head 213a toward the backup stage 202, and compression bonds the plurality of terminals of the electronic circuit board 60 with the plurality of terminals TM. Note that the above-described position alignment may be performed at the point in time at which the electronic circuit board 60 is inserted into the pressing device 316.

When the compression bonding is complete, as illustrated in FIG. 10E, the compression bonding device 213 moves the compression bonding head 213a upward and returns the compression bonding head 213a to the pre-compression bonding position. At the same time, the control unit 220 returns the pressing device 316 to a pre-pressing position. Note that the control unit 220 may release the pressing of the non-active region NA by the base 316a of the pressing device 316, before or during the compression bonding by the compression bonding head 213a. Further, when the compression bonding is complete, the suction device 212 stops the suction with respect to the movable stage 201 and the backup stage 202. After that, the transport device 214 transports the flexible display 2a on which the electronic circuit board 60 is mounted to a subsequent process.

Note that, similarly to the above-described first embodiment, the suction device 212 need not necessarily perform the suction during the pressing of the non-active region NA by the base 316a of the pressing device 316.

### Second Embodiment

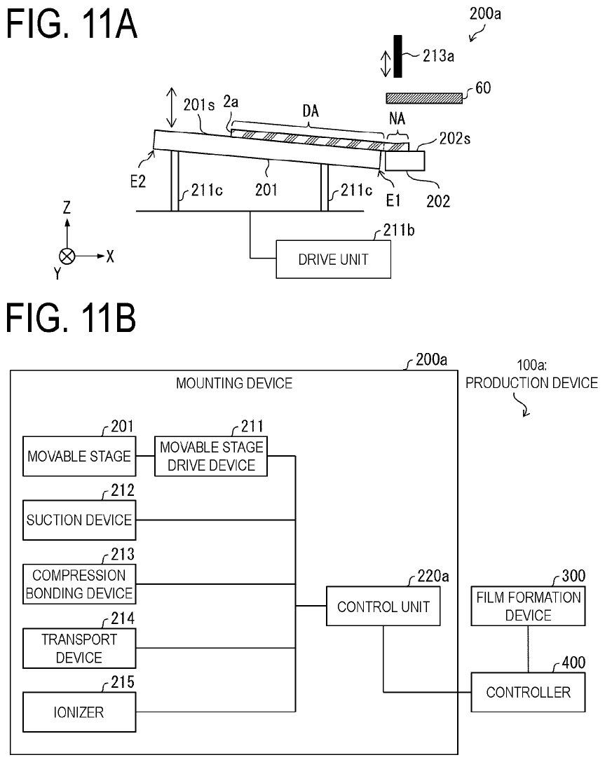

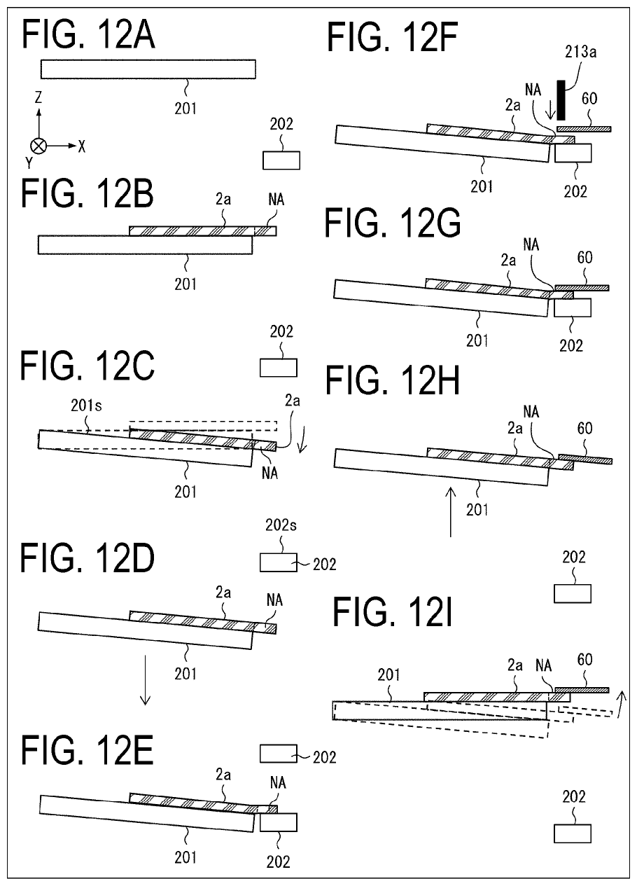

A description follows regarding another embodiment of the disclosure, with reference to FIGS. 11A and 11B, and FIGS. 12A to 12I. Note that, for explanatory convenience, members having the same function as the members described in the above-described embodiment will be assigned the same reference signs, and a description thereof will be omitted. FIG. 11A is a schematic diagram illustrating a configuration example of a mounting device 200a, and FIG. 11B is a block diagram illustrating the configuration example of the mounting device 200a. FIGS. 12A to 12I are a flowchart illustrating an example of a mounting method of the electronic circuit board 60 onto the flexible display 2a.

The present embodiment differs from the first embodiment in that the movable stage 201 is inclined with respect to the backup stage 202, and in that state, the non-active region NA protruding from the movable stage 201 is placed on the backup stage 202.

### Production Device

As illustrated in FIG. 11B, a production device 100a of the flexible display 2 is provided with the mounting device 200a (to be described below), the film formation device 300, and the controller 400.

### Mounting Device

As illustrated in FIGS. 11A and 11B, the mounting device 200a includes the movable stage 201, the backup stage 202, the movable stage drive device 211, the suction device 212, the compression bonding device 213, the transport device 214, and the ionizer 215. Furthermore, the mounting device 200a is provided with a control unit 220a that performs overall control of the movable stage drive device 211, the suction device 212, the compression bonding device 213, the transport device 214, and the ionizer 215. The mounting device 200a differs from the mounting device 200 in not being provided with the pressing device 216. Furthermore, the mounting device 200a differs from the mounting device 200 in the following points.

In addition to the movement similar to that of the first embodiment, the movable stage 201 moves in the Z axis direction (the up-down direction) with respect to the backup stage 202. The movement of the movable stage 201 in the Z axis direction is also performed by the movable stage drive device 211.

The movable stage drive device 211 supports the movable stage 201 and also moves the movable stage 201 in the X axis, the Y axis, or the Z axis direction. For example, the movable stage drive device 211 is provided with telescopic members 211c that are connected to the lower face of the movable stage 201, that support the movable stage 201, and that also expand and contract in the up-down direction. In addition to the movement of the movable stage 201 in the X axis or the Y axis direction, the drive unit 211b also performs control to drive (expand and contract) the telescopic members 211c, thus also controlling the movement of the movable stage 201 in the Z axis direction. The telescopic portion 211c is, for example, an air cylinder.

Furthermore, the movable stage 201 can be inclined with respect to the backup stage 202. More specifically, the movable stage 201 can be inclined such that an end portion E1 of the movable stage 201 on the backup stage 202 side is below an end portion E2 on the other end side of the movable stage 201 (inclined in a direction in which a surface 201s faces a surface 202s). The movement in the up-down direction, and the inclination operation of the movable stage 201 is performed by the movable stage drive device 211. More specifically, when inclining the movable stage 201, the movable stage drive device 211 contracts the telescopic member 211c on the side of the end portion E1, for example. When moving the movable stage 201 in the up-down direction, the inclined state is maintained, and the telescopic members 211c on the end portion E1 side and on the end portion E2 side are expanded or contracted at the same speed.

The control unit 220a controls the movable stage drive device 211 to move the movable stage 201 from above the backup stage 202 as far as the backup stage 202, while the movable stage 201 remains in the inclined state with respect to the backup stage 202, and places the non-active region NA on the backup stage 202. At the time of the placement on the backup stage 202 as a result of the movement of the movable stage 201 in the inclined state, a pressing force is generated that presses the non-active region NA against the backup stage 202. This makes effective use of a “copy (flexible)” characteristic of the flexible display 2a.

Thus, in the present embodiment, the control unit 220a that causes the movable stage 201 to be inclined in the direction in which the surface 201s faces the surface 202s, in the state in which the non-active region NA is placed on the movable stage 201 so as to face the backup stage 202, and the movable stage 201 to move as far as the backup stage 202 in that state (the movable stage drive device 211 that is driven by the control from the control unit 220a) functions as a pressing unit that generates the pressing force.

Note that, an inclination angle of the movable stage 201 with respect to the backup stage 202, and a length W2b (see FIG. 6) of the flexible display 2a that is caused to protrude from the movable stage 201 may be set to such an extent that the sufficient pressing force is generated in order to level the non-active region NA placed on the backup stage 202. The inclination angle is several degrees, for example. Furthermore, the materials of the upper film 10 and the backup stage 202 may be selected in order to facilitate the generation of the pressing force.

In addition, when inclining the movable stage 201, in a case of using only the suction by the suction device 212, the flexible display 2a may fall from the movable stage 201, or a placement position thereof may be displaced. Furthermore, in the case of using only the suction, due to the pressing force generated when placing the non-active region NA on the backup stage 202, the active region DA placed on the movable stage 201 may move with respect to the movable stage 201 (may lift up), and thus the generated pressing force may decrease. In this case, the non-active region NA may not be sufficiently leveled. As a result, to prevent the above from occurring, a fixing mechanism (not illustrated) is preferably provided on the movable stage 201, which fixes the flexible display 2a to the movable stage 201, by clamping, together with the movable stage 201, the flexible display 2a placed on the movable stage 201. The control unit 220a controls the fixing mechanism and clamps the flexible display 2a between the fixing mechanism and the movable stage 201.

### Mounting Method

Next, a mounting method (mounting processing) of the electronic circuit board 60 onto the plurality of terminals TM of the flexible display 2a, by the mounting device 200a, will be described with reference to FIGS. 12A to 12I. The present mounting method is realized by each of the above-described devices being controlled by the control unit 220a.

As illustrated in FIG. 12A, with respect to the movable stage 201 on which the flexible display 2a has not yet been placed (the initial state), the movable stage 201 is positioned above the backup stage 202. In this state, as illustrated in FIG. 12B, the transport device 214 places the flexible display 2a on the movable stage 201 such that the non-active region NA protrudes from the movable stage 201 and faces the backup stage 202. When the flexible display 2a is placed on the movable stage 201, the suction device 212 starts the suction, and causes the flexible display 2a to be sucked against the movable stage 201. Furthermore, in the present embodiment, at that time, the control unit 220a controls the fixing mechanism and fixes the flexible display 2a to the movable stage 201.

When the placement and fixing of the flexible display 2a on the movable stage 201 is complete, as illustrated in FIG. 12C, the control unit 220a controls the movable stage drive device 211, and inclines the movable stage 201 with respect to the backup stage 202 such that the surface 201s faces the surface 202s. In other words, the flexible display 2a placed on the movable stage 201 is inclined with respect to the backup stage 202 (an inclining process).

After that, as illustrated in FIG. 12D, in the state in which the movable stage 201 is inclined, the control unit 220a causes the movable stage 201 to be moved from the initial state to a position at which the side surface of the movable stage 201 faces the side surface of the backup stage 202 (a movement process). In other words, from above the backup stage 202, the flexible display 2a placed on the movable stage 201 is moved. As illustrated in FIG. 12E, when the movable stage 201 has been moved as far as the position in which both the side surfaces face each other, the non-active region NA is placed on the backup stage 202 (a placement process). At that time, the non-active region NA is pressed against the backup stage 202.

As a result of the inclining process, the movement process, and the placement process illustrated in FIGS. 12C to 12E, a pressing process is implemented in which the pressing force is generated that presses the non-active region NA against the backup stage 202.

Furthermore, as illustrated in FIG. 12E, the control unit 220a drives the movable stage drive device 211 and moves the movable stage 201. In this way, the non-active region NA is placed in the predetermined position on the backup stage 202. After the position alignment on the predetermined position, the suction device 212 starts the suction, and causes the placed non-active region NA to be sucked against the backup stage 202 (a suction process).

After the non-active region NA is placed on and fixed to the backup stage 202, as illustrated in FIG. 12F, the transport device 214 transports the electronic circuit board 60 to a position above the non-active region NA. Processes illustrated in FIGS. 12F and 12G are the same as the processes illustrated in FIGS. 7D and 7E, respectively.

After that, after the control unit 220a has moved the movable stage 201, on which is placed the flexible display 2a on which the electronic circuit board 60 is mounted, upward (to the position of the initial state), as illustrated in FIG. 12H, the control unit 220a returns the inclined movable stage 201 to the initial state (the state in which the surface 201s is substantially parallel to the surface 202s), as illustrated in FIG. 12I. After the movable stage 201 is returned to the initial state, the suction device 212 stops the suction with respect to the movable stage 201. Furthermore, at that time, the control unit 220a controls the fixing mechanism and releases the fixing of the flexible display 2a to the movable stage 201.

Note that, in the present mounting method, the inclination control of the movable stage 201 is performed, but the movable stage 201 may be provided in a state of being inclined in advance. In this case, the inclination control is not necessarily performed.

### Effects of Present Embodiment

In the present embodiment, the movable stage 201 on which the flexible display 2a is placed is moved from above the backup stage 202 in the state in which the movable stage 201 is inclined with respect to the backup stage 202, and the non-active region NA is placed on the backup stage 202. In this way, the non-active region NA can be pressed against the backup stage 202 and can be leveled. Specifically, in this processing, after the non-active region NA has been placed on the backup stage 202, the non-active region NA can be leveled without performing a so-called secondary operation (secondary action) in which the non-active region NA is pressed against the backup stage 202 using the pressing member 216a or the like.

### Third Embodiment

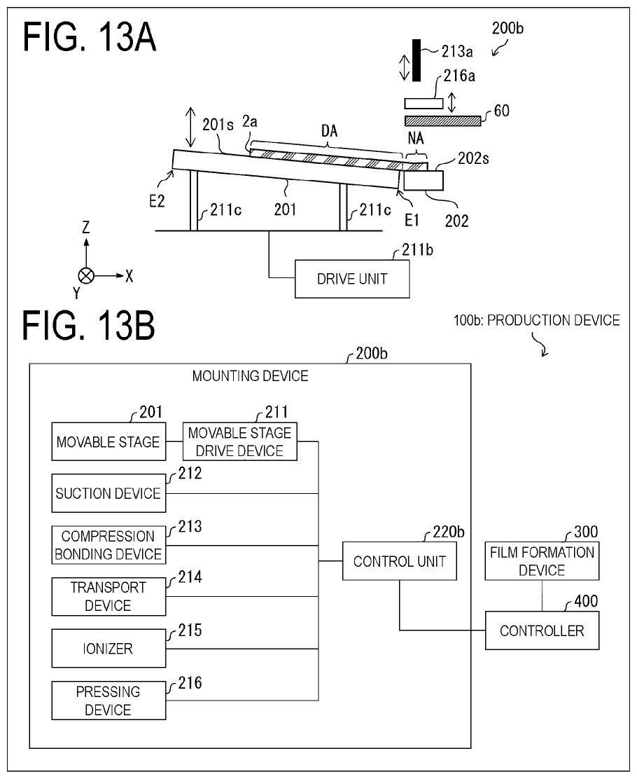

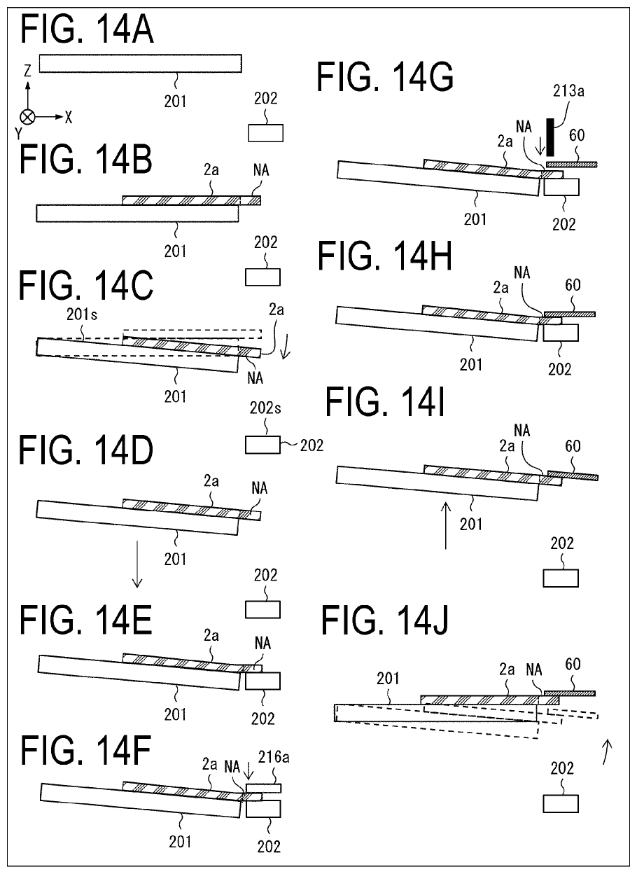

A description follows regarding another embodiment of the disclosure, with reference to FIGS. 13A and 13B, and FIGS. 14A to 14J. Note that, for explanatory convenience, members having the same function as the members described in the above-described embodiments will be assigned the same reference signs, and a description thereof will be omitted. FIG. 13A is a schematic diagram illustrating a configuration example of a mounting device 200b, and FIG. 13B is a block diagram illustrating a configuration example of the mounting device 200b. FIGS. 14A to 14J are a flowchart illustrating an example of a mounting method of the electronic circuit board 60 onto the flexible display 2a. The mounting device 200b according to the present embodiment is a combination of the mounting devices 200 and 200a of the first and second embodiments.

### Production Device

As illustrated in FIG. 13B, a production device 100b of the flexible display 2 is provided with the mounting device 200b (to be described below), the film formation device 300, and the controller 400.

### Mounting Device

The mounting device 200b illustrated in FIG. 13A and 13B, is the mounting device 200a illustrated in FIG. 11B to which the functions of the pressing device 216 and the pressing member 216a of the mounting device 200 have been added. Thus, a control unit 220b has the functions of the control units 220 and 220a.

### Mounting Method

Next, a mounting method (mounting processing) of the electronic circuit board 60 onto the plurality of terminals TM of the flexible display 2a, by the mounting device 200b, will be described with reference to FIGS. 14A to 14J. The present mounting method is realized by each of the above-described devices provided in the mounting device 200b being controlled by the control unit 220b.

Processes illustrated in FIGS. 14A to 14E are the same as the processes illustrated in FIGS. 12A to 12E. In these processes, when the flexible display 2a has been placed on the movable stage 201, the movable stage 201 is inclined and moved to the backup stage 202, and the non-active region NA is placed on the backup stage 202. In this way, the pressing force is generated to press the non-active region NA against the backup stage 202, and the non-active region NA is leveled.

After the non-active region NA is placed on the backup stage 202 and is fixed by the suction of the suction device 212, the suction device 212 temporarily stops the suction with respect to the backup stage 202. As illustrated in FIG. 14F, after the pressing device 216 moves the pressing member 216a to the position above the non-active region NA, similarly to FIG. 7C, the pressing device 216 uses the pressing member 216a to press the non-active region NA against the backup stage 202. In this way, once again, the non-active region NA is leveled. After the non-active region NA is leveled, the pressing device 216 returns the pressing member 216a to the pre-pressing position. Furthermore, at that time, the suction device 212 once again starts the temporarily stopped suction.

Processes illustrated in FIGS. 14G to 14J are the same as the processes illustrated in FIGS. 12F to 12I. In these processes, the electronic circuit board 60 is mounted on the flexible display 2a, and after mounting, the movable stage 201 is moved back to the position of the initial state. After that, the inclination of the movable stage 201 is returned to an original state.

### Effects of Present Embodiment

In this way, in the present mounting method, the process generating the pressing force to press the non-active region NA against the backup stage 202 is performed twice, at (1) and (2) described below.

(1) The processes by which the non-active region NA is placed on the backup stage 202 in the inclined state (the processes illustrated in FIGS. 14C to 14E).

(2) The pressing process using the pressing member 216a to press the non-active region NA placed on the backup stage 202 (the process illustrated in FIG. 14F). Thus, in comparison to the first and second embodiments, the non-active region NA can be leveled even more.

### Modified Example

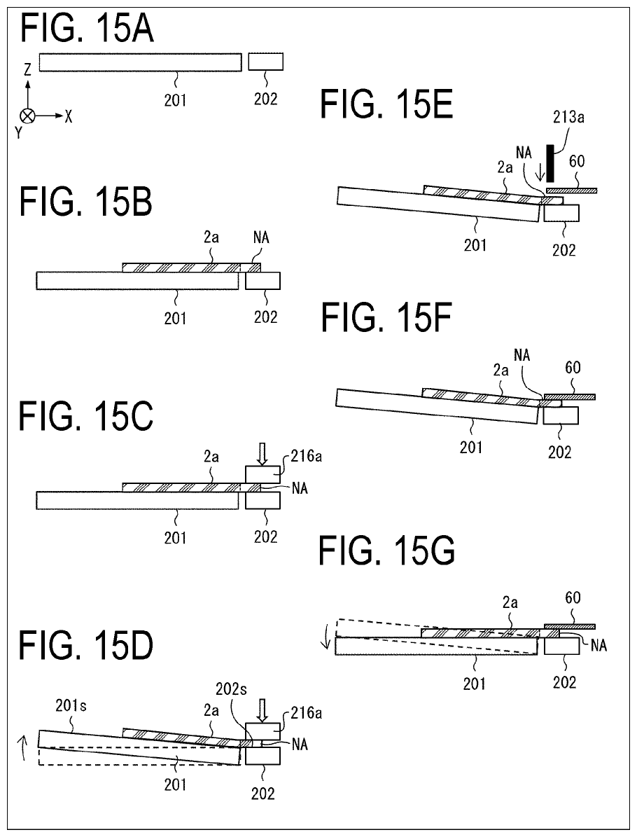

Next, a modified example of the third embodiment will be described with reference to FIGS. 15A to 15G. FIGS. 15A to 15G are a flowchart illustrating an example of a mounting method of the electronic circuit board 60 onto the flexible display 2a.

In the above-described third embodiment, the movable stage 201 is moved in the up-down direction, but in the present modified example, the movable stage 201 is not moved in the up-down direction. More specifically, in the present modified example, the movable stage 201, the movable stage drive device 211, and the control unit 220b include a function to move the movable stage 201 in the X axis and Y axis directions, and a function to incline the movable stage 201.

### Mounting Method

Processes illustrated in FIGS. 15A to 15C are the same as the processes illustrated in FIGS. 7A to 7C. However, in FIG. 15B, the control unit 220b controls the fixing mechanism described in the second embodiment, and fixes the flexible display 2a to the movable stage 201. In a state in which the pressing device 216 presses the non-active region NA using the pressing member 216a, as illustrated in FIG. 15C, the control unit 220b controls the movable stage drive device 211 and inclines the movable stage 201 with respect to the backup stage 202 such that the surface 201s faces the surface 202s, as illustrated in FIG. 15D. In this way, in the present mounting method, the above-described pressing force is generated by using the pressing member 216a as well as inclining the movable stage 201 with respect to the backup stage 202.

After the non-active region NA is pressed and leveled, the pressing device 216 returns the pressing member 216a to the pre-pressing position. After that, as illustrated in FIG. 15E, the transport device 214 transports the electronic circuit board 60 to a position above the non-active region NA, and aligns the position of the electronic circuit board 60 with respect to the flexible display 2a. When the position alignment is complete, the compression bonding device 213 moves the compression bonding head 213a toward the backup stage 202, and compression bonds the plurality of terminals of the electronic circuit board 60 with the plurality of terminals TM. A state obtained when the compression bonding is complete is illustrated in FIG. 15F. When the compression bonding is complete, after the compression bonding device 213 moves the compression bonding head 213a upward (to the pre-compression bonding position), the inclined movable stage 201 is returned to the initial state (the state in which the surface 201s is substantially parallel to the surface 202s), as illustrated in FIG. 15G. After the movable stage 201 is returned to the initial state, the suction device 212 stops the suction with respect to the movable stage 201. Furthermore, at that time, the control unit 220b controls the fixing mechanism and releases the fixing of the flexible display 2a to the movable stage 201. After that, the transport device 214 transports the flexible display 2a on which the electronic circuit board 60 is mounted to a subsequent process.

Note that although the suction is started by the suction device 212 in FIG. 15B, in the present modified example also, the suction may be temporarily stopped in the pressing state illustrated in FIGS. 15C and 15D, and after the pressing is complete, the suction may be once more started.

### Other Configurations

In the above-described embodiments, the mounting processing is described as being performed by the control of the control units 220, 220a, and 220b, but the control may be performed manually. Examples of this include: (1) pressing using the pressing member 216a or the base 316a of the first and third embodiments; (2) the placing and the position alignment of the flexible display 2a; (3) the movement and inclination operation of the movable stage 201; and (4) the driving of the suction device 212 and the compression bonding device 213. In this case, the mounting devices 200, 200a, and 200b need not necessarily be provided with the movable stage drive device 211, the transport device 214, and the pressing device 216. However, taking into account the mass production of the flexible display 2, the mounting processing is preferably performed using the automatic control of the control units 220, 220a, and 220b.

Furthermore, in the first embodiment, the movable stage 210 is configured not to move in the up-down direction, but may move in the up-down direction. In this case, when the movable stage 201 is positioned above the backup stage 202, the flexible display 2a is placed on the movable stage 201, and after that, the movable stage 201 is moved as far as the backup stage 202. After the mounting of the electronic circuit board 60, the movable stage 201 is returned to the original position, and the flexible display 2a on which the electronic circuit board 60 is mounted is transported to a subsequent process.

In addition, in the first and third embodiments, while the non-active region NA is being pressed against the backup stage 202 by the pressing member 216a or the base 316a of the pressing device 316, the suction state of the non-active region NA with respect to the backup stage 202 is released, so that the leveling of the non-active region NA is not obstructed. As long as the leveling is not obstructed, instead of releasing the suction state (temporarily stopping the suction state), the suction force may be weakened, for example. Furthermore, as long as it is a configuration that does not obstruct the leveling, the suction state need not necessarily be released.

### Example of Realization by Software

Control blocks (in particular, the control units 220, 220a, and 220b) of the mounting devices 200, 200a, and 200b may be realized by a logic circuit (hardware) formed in an integrated circuit (IC) chip or the like, or may be realized by software using a Central Processing Unit (CPU).

In the case of the latter, each of the mounting devices 200, 200a, and 200b is provided with a CPU that executes instructions of a program that is software to realize various functions, a Read Only Memory (ROM) or a storage device (these are referred to as a “storage medium”) in which the above-described program and various data are stored so as to be readable by a computer (or the CPU), a Random Access Memory (RAM) that temporary stores the above-described program, and the like. Then, by the computer (or the CPU) reading out and executing the above-described program from the above-described storage medium, the object of the disclosure is achieved. As the above-described storage medium, a “non-transitory concrete medium,” such as a tape, a disk, a card, a semiconductor memory, or a programmable logic circuit can be used. Furthermore, the above-described program may be supplied to the above-described computer via a chosen transmission medium that can transmit the program (a communication network, broadcast waves, or the like). Note that an aspect of the disclosure can also be realized in the format of data signals that are embedded in carrier waves in which the program is realized by electronic transmission.

### Supplement

A mounting method according to a first aspect of the disclosure is a mounting method for mounting an electronic circuit board (60) onto terminals (TM) included in a non-display region (non-active region NA) of a flexible display (2a) that includes a display region (active region DA) and the non-display region surrounding the display region. The mounting method includes generating a pressing force that presses the non-display region against a placement stage (backup stage 202) configured to allow the non-display region to be placed, and compression bonding the electronic circuit board to the terminals, after the non-display region is pressed against the placement stage using the pressing force generated in the generating a pressing force.

According to the above-described configuration, the non-display region including the terminals can be leveled by the pressing force. As a result, the electronic circuit board can be mounted onto the terminals of the leveled non-display region, and thus, the electronic circuit board can be mounted with a high degree of accuracy.

In addition, with respect to the first aspect, in the mounting method according to a second aspect of the disclosure, in the generating a pressing force, the pressing force may be generated using a pressing member (216a, base 316a), in a state in which the non-display region is placed on the placement stage.

According to the above-described configuration, the non-display region can be leveled using the pressing member.

Furthermore, with respect to the first and second aspects, in the mounting method according to a third aspect of the disclosure, in the generating a pressing force, the flexible display may be placed on a movable stage (201) configured to move up and down with respect to the placement stage, and the pressing force may be generated by causing the movable stage in an inclined state to move from above the placement stage and to place the non-display region onto the placement stage.

With respect to the third aspect, in the mounting method according to a fourth aspect of the disclosure, the generating a pressing force may include: inclining the movable stage with respect to the placement stage in a state in which the flexible display is placed on the movable stage; moving the movable stage inclined as far as the placement stage; and placing the non-display region onto the placement stage when the movable stage has moved as far as the placement stage.

According to the above-described configuration, the pressing force is generated by causing the flexible display in the inclined state to be moved to the placement stage and the non-display region to be placed onto the placement stage. Thus, the non-display region can be leveled by this processing.

Furthermore, with respect to the first aspect, in the mounting method according to a fifth aspect of the disclosure, in the generating a pressing force, in a state in which the flexible display is placed on the placement stage and on the movable stage, and the non-display region is placed on the placement stage, the pressing force may be generated using the pressing member and also by inclining the movable stage with respect to the placement stage, the movable stage being able to be inclined with respect to the placement stage.

According to the above-described configuration, as well as using the pressing member, the pressing force is also generated by inclining the movable stage with respect to the placement stage. Thus, the non-display region can be leveled by this processing.

Furthermore, with respect to any one of the first to fifth aspects, a sixth aspect of the disclosure may include applying suction, in which the non-display region is caused to be sucked against the placement stage.

According to the above-described configuration, the non-display region can be fixed to the placement stage.

Furthermore, with respect to the sixth aspect, in the mounting method according to a seventh aspect of the disclosure, in the applying suction, while the pressing force is being generated in the generating a pressing force, a suction state of the non-display region with respect to the placement stage may be released.

According to the above-described configuration, a possibility can be reduced of the leveling of the non-display region being obstructed by the suction.

Furthermore, a mounting device according to an eighth aspect of the disclosure is a mounting device (200, 200a, 200b) configured to mount an electronic circuit board onto terminals included in a non-display region, of a flexible display that includes a display region and the non-display region surrounding the display region. The mounting device includes: a pressing unit (pressing device 216, 316, pressing member 216a, base 316a, movable stage drive device 211, control unit 220, 220a, 220b) configured to generate a pressing force that presses the non-display region against a placement stage configured to allow the non-display region to be placed; and a compression bonding unit (compression bonding device 213, compression bonding head 213a) configured to compression bond the electronic circuit board to the terminals of the non-display region pressed against the placement stage using the pressing force generated by the pressing unit.

According to the above-described configuration, the same effects can be achieved as of the first aspect.

Furthermore, a production device according to a ninth aspect of the disclosure is a production device (100, 100a, and 100b) configured to produce a flexible display (2). The production device includes the mounting device according to the eighth aspect.

According to the above-described configuration, the flexible display can be produced on which the electronic circuit board is accurately mounted.

### Other

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

2, 2a Flexible display device
60 Electronic circuit board
100, 100a, 100b Production device
200, 200a, 200b Mounting device
201 Movable stage
202 Backup stage (placement stage)
211 Movable stage drive device (pressing unit)
213 Compression bonding device (compression bonding unit)
213a Compression bonding head (compression bonding unit)
216 Pressing device (pressing unit)
216a Pressing member
220, 220a, 220b Control unit (pressing unit)
316 Pressing device (pressing unit)
316a Base (pressing member)
DA Active region (display region)
NA Non-active region (non-display region)
TM Terminal

1-2. (canceled)

3. A mounting method for mounting an electronic circuit board onto terminals included in a non-display region of a flexible display that includes a display region and the non-display region surrounding the display region, the mounting method comprising:
generating a pressing force that presses the non-display region against a placement stage configured to allow the non-display region to be placed; and
compression bonding the electronic circuit board to the terminals, after the non-display region is pressed against the placement stage using the pressing force generated in the generating a pressing force,
wherein, in the generating a pressing force, the flexible display is placed on a movable stage configured to move up and down with respect to the placement stage, and
the pressing force is generated by causing the movable stage in an inclined state to move from above the placement stage and to place the non-display region onto the placement stage.

4. The mounting method according to claim 3,
wherein the generating a pressing force includes:
inclining the movable stage with respect to the placement stage in a state in which the flexible display is placed on the movable stage;
moving the movable stage inclined as far as the placement stage; and
placing the non-display region onto the placement state in a case that the movable stage is moved as far as the placement stage.

5. A mounting method for mounting an electronic circuit board onto terminals included in a non-display region of a flexible display that includes a display region and the non-display region surrounding the display region, the mounting method comprising:
generating a pressing force that presses the non-display region against a placement stage configured to allow the non-display region to be placed; and
compression bonding the electronic circuit board to the terminals, after the non-display region is pressed against the placement stage using the pressing force generated in the generating a pressing force,
wherein, in the generating a pressing force, in a state in which the flexible display is placed on the placement stage and the movable stage, and the non-display region is placed on the placement stage, the pressing force is generated using the pressing member and also by inclining the movable stage with respect to the placement stage, the movable member being able to be inclined with respect to the placement stage.

6-9. (canceled)

10. The mounting method according to claim 3,
wherein, in the generating a pressing force, the pressing force is generated using a pressing member, in a state in which the non-display region is placed on the placement stage.

11. The mounting method according to claim 5,
wherein, in the generating a pressing force, the pressing force is generated using a pressing member, in a state in which the non-display region is placed on the placement stage.

12. The mounting method according to claim 3, further comprising:
applying suction in which the non-display region is caused to be sucked against the placement stage.

13. The mounting method according to claim 4, further comprising:
applying suction in which the non-display region is caused to be sucked against the placement stage.

14. The mounting method according to claim 5, further comprising:
applying suction in which the non-display region is caused to be sucked against the placement stage.

15. The mounting method according to claim 12,
wherein, in the applying suction, while the pressing force is being generated in the generating a pressing force, a suction state of the non-display region with respect to the placement stage is released.

16. The mounting method according to claim 13,
wherein, in the applying suction, while the pressing force is being generated in the generating a pressing force, a suction state of the non-display region with respect to the placement stage is released.

17. The mounting method according to claim 14,
wherein, in the applying suction, while the pressing force is being generated in the generating a pressing force, a suction state of the non-display region with respect to the placement stage is released.
